(19) United States
(12) Patent Application Publication
(10) Pub. No.: US 2012/0093342 A1
(43) Pub. Date: Apr. 19, 2012

(54) MICROPHONE LINK SYSTEM

(76) Inventors: Matthias Rupprecht, Straubenhardt (DE); Marek Neumann, Karlsruhe (DE); Peter Kalbus, Karlsruhe (DE)

(21) Appl. No.: 13/273,933

(22) Filed: Oct. 14, 2011

(30) Foreign Application Priority Data
Oct. 14, 2010 (EP) 10 187 586.2

(51) Int. Cl. H03G 3/00; H04R 3/00

(52) U.S. Cl. 381/107; 381/122

(57) ABSTRACT

A microphone link system comprises a microphone that coverts an acoustic sound signal into an electrical sound signal, a slave unit that receives the electrical sound signal, a master unit, and a bus connecting the slave unit to the master unit. The slave unit comprises an analog-to-digital converter that converts the electrical sound signal into a digital sound signal; a signal processor that receives and processes the digital sound signal into a data signal; and a bus interface connected between the signal processor and the bus. The bus interface provides to the slave unit electrical power taken from the bus, sends the data signal to the master unit via the bus and receives from and sends to the master unit control signals via the bus.

### 1. CLAIM OF PRIORITY

This patent application claims priority from EP Application No. 10 187 586.2 filed Oct. 14, 2010, which is hereby incorporated by reference.

### 2. FIELD OF TECHNOLOGY

The invention relates to a microphone link system, in particular comprising a master unit, at least one slave unit and a bus connecting the master unit and the at least one slave unit.

### 3. RELATED ART

In numerous applications such as music recording, public address (PA) or automobile applications, it is required to collect at a master unit signals from a plurality of remotely located microphones. The microphones are often connected to the master unit by cables over which electrical power and analog sound signals are conveyed. The interconnecting cabling can contribute substantial cost to an overall system especially where a large number of microphones are employed. Moreover, implementation of such a system is relatively cumbersome because of the interconnection of separate cables between the master unit and those of the microphones. In automobile applications, the weight added by the multiplicity of cables and the vulnerability to noise are additional aspects to be carefully considered.

There is a need for an improved microphone link system.

### SUMMARY OF THE INVENTION

According to an aspect of the invention, a microphone link system comprises a microphone that converts an acoustic sound signal into an electrical sound signal, which is provided to a slave unit, and a bus that connects the slave unit to a master unit. The slave unit comprises an analog-to-digital converter converts the electrical sound signal into a digital sound signal; a signal processor receives and processes the digital sound signal into a data signal; and a bus interface connected between the signal processor and the bus. The bus interface provides the slave unit with electrical power taken from the bus, and sends the data signal to the master unit via the bus and receives from and sends to the master unit control signals via the bus.

These and other objects, features and advantages of the present invention will become apparent in the detailed description of the best mode embodiment thereof, as illustrated in the accompanying drawings. In the figures, like reference numerals designate corresponding parts.

### DESCRIPTION OF THE DRAWINGS

FIG. 1 is a block diagram illustration of a microphone link system; and

FIG. 2 is a block diagram illustration of a slave unit employed in the microphone link system of FIG. 1.

### DETAILED DESCRIPTION OF THE INVENTION

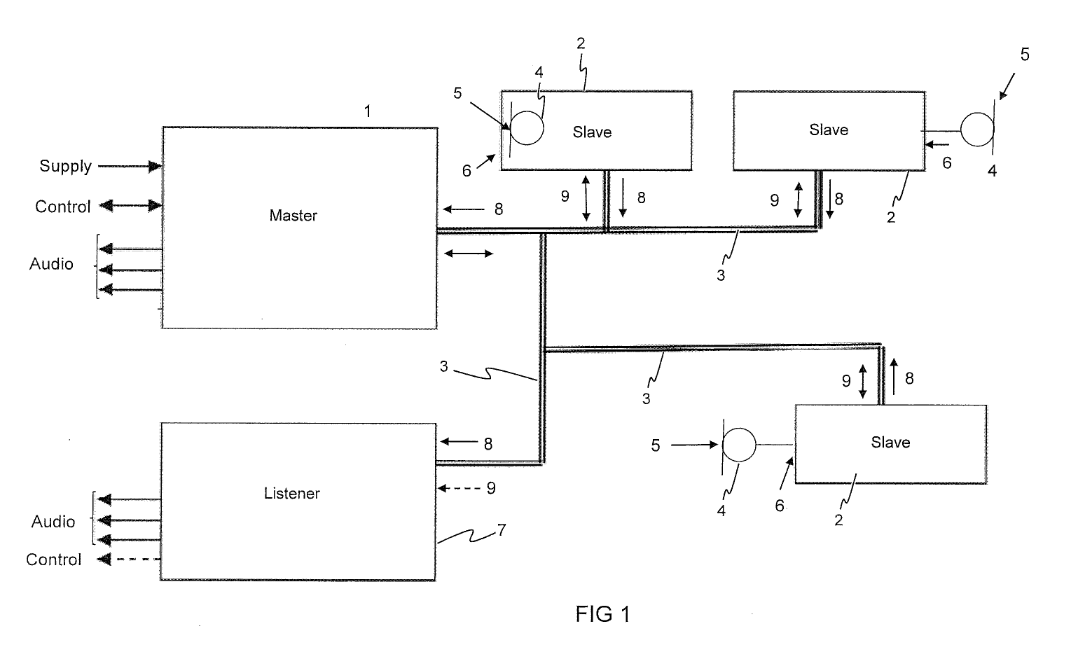

FIG. 1 a illustrates microphone link system that includes a master unit 1, a plurality of slave units 2 (e.g., three in this embodiment), a bus 3 and a plurality of microphones 4 (e.g., three in this embodiment). Each of the microphones 4 is connected to its respective slave unit 2 and converts an acoustic sound 5 signal into an electrical sound signal 6. The bus 3 connects the slave units 2 to the master unit 1 and, as the case may be, to a listener unit 7. Each of the slave unit 2 provides a data signal 8 indicative of the processed electrical sound signal 6. The microphones 4 may be single transducers, or at least one of the microphones may include an array of transducers that provide a plurality of electrical sound signals 6 to its respective slave unit 2. The microphones 4 may be integrated within the slave unit 2 as indicated in FIG. 1.

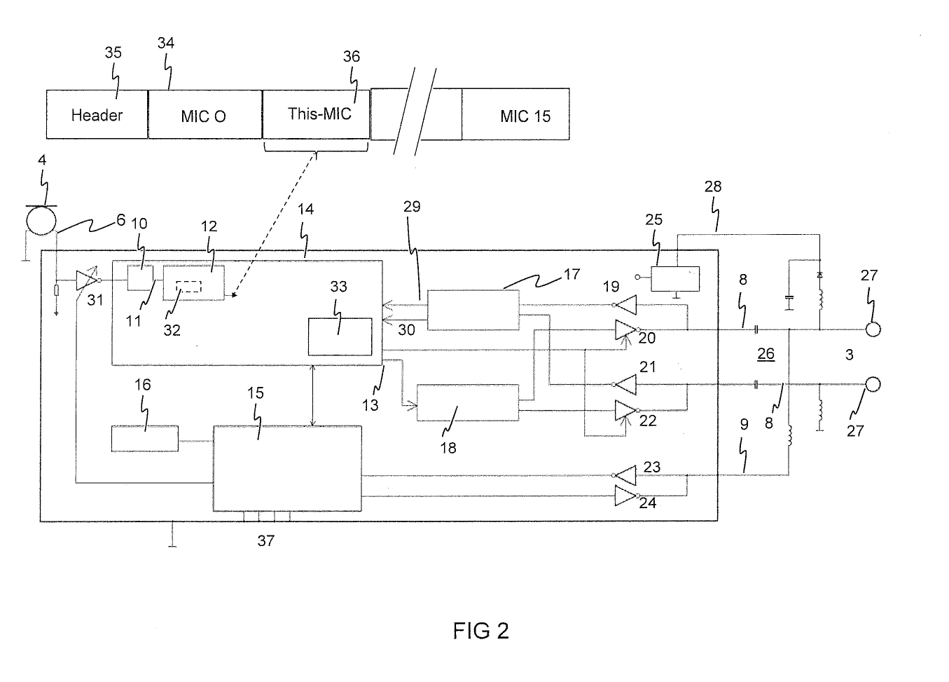

Referring to FIG. 2, each of the slave units 2 includes an analog-to-digital converter 10 that converts the electrical sound signal 6 into a digital sound signal 11. A signal processor 12 receives and processes the digital sound signal 11, to provide a data signal 13. The signal processor 12 may be a dedicated programmable digital signal processor (DSP) and be included in an integrated circuit 14, which may also include the analog-to-digital converter 10 or any other circuitry. A bus interface is connected between the signal processor 12 and the bus 3 (FIG. 1), which sends the data signal 13 to the master unit 1 (FIG. 1) via the bus 3 in a coded, modulated or direct manner or otherwise. The bus interface also receives from and sends to the master unit 1 the control signals 9 via the bus 3, and provides to the slave unit 2 electrical power taken from the bus 3. The electrical power may be supplied by the master station 1.

The bus interface includes a microcontroller 15 that includes a non-volatile memory 16 (e.g., a flash memory); a clock recovery and synchronization circuit 17; a data transmitter circuit 18; line drivers 20, 22, 24; line receivers 19, 21, 23; and a voltage regulator 25. The bus interface, in particular the line drivers 20, 22, 24 and line receivers 19, 21, 23 may interact with a passive line filter circuitry 26 that separates different frequency bands when power, control signals and data signal are transmitted in different frequency bands. In this embodiment, the control signals 9 maybe transmitted in an asymmetric mode as a unipolar signal and the data signal 8 is transmitted in a symmetric mode as a differential signal.

In this embodiment, power may be transmitted by way of direct current (DC) or alternatively at a very low frequency (e.g., <100 Hz). The control signals 9 are transmitted in a medium frequency band (e.g., 10-100 kHz) and the data signals 8 are transmitted at a higher frequency band (e.g., >100 kHz). The line filter circuitry 26 splits the received signal into the direct current (DC) for power supply, the control signals 9 and the data signals 8. The direct current (DC) is fed to the voltage regulator 25 to generate one or more constant supply voltages 28 for the slave unit 2 and, eventually, the microphone 4.

When power, control signals and data signal are transmitted in different frequency bands, the data transmitter circuit 18 may include a modulator to modulate a high frequency carrier with the data signal 13. However, all known methods for separating the data signal from the control signals are applicable, e.g., transmitting the data signal at a higher clock rate than those of the control signals. The clock rate in the higher frequency band, which may be provided by the master unit 1, is recovered by the clock recovery and synchronization circuit 17 which serves as a (controlled) clock generator and provides a clock signal 29 to the signal processor 12. When, as in the present example, the data signals 8 are transmitted using a frame structure that may be determined by the master unit 1, the clock recovery and synchronization circuit 17 may read the data from the channel for the data signals 8 and extract therefrom for the signal processor 12, the analog-to-digital converter 10, et cetera, the clock and the frame structure on the bus 3 as established by the master unit 1 and provide the clock signal 29 and a synchronization signal 30 (e.g., for the frame structure) to the signal processor 12.

The control signals 9 which are in the medium frequency band may be generated or received by the microcontroller 15 via the line filter circuitry 26 which, in turn, is connected to an unshielded two-wire twisted pair line 27 forming the bus 3. The microcontroller 15 controls a variable gain preamplifier 31 that is connected between the microphone 4 and the analog-to-digital converter 10, the gain being dependent on a first one of the control signals 9 received from the master unit 1 and being adapted by the microcontroller 15 to maintain a sufficient amplitude of the electrical sound signal 6.

The slave unit 2 may generate from the (amplified) electrical sound signal 6 a second one of the control signals 9 transmitted to the master unit. For example, the second one of the control signals 9 may be generated when the acoustic sound signal exceeds and/or falls below a trigger sound level so that, e.g., the master unit 1 is informed of whether the slave unit 2 is active or in an idle mode due to the strength of the acoustic sound signal or whether the slave unit 2 will transmit the data signal 8 upon transmission of the second one of the control signals 9. The data signals 8 may be coded by a coder 33 with a specific code prior to transmission. The code used may be such that it makes the data signal more resistant to noise occurring on the transmission line. Suitable codes are, for example, the non-return-to-zero (NRZ) code, the Manchester code or any kind of spread code that adds redundancy to the data to be transmitted. Furthermore, the data to be transmitted may be compressed (e.g., VLC, WMA, MP3, etc.) in the slave unit 2, and, accordingly, decompressed in the master unit 1 in order to keep the data rate low at which data are transmitted on the bus 3.

A digital filter 32 having controllable filter parameters may be implemented in the signal processor 12. The filter parameters may be controlled by the microcontroller 15 in accordance with a third one of the control signals received from the master unit 1. With the digital filter 32, acoustic noise picked up by the microphone 4 may be filtered out by limiting the bandwidth of the digital sound signal 11 to, for instance, 300 to 3400 Hz when speech is recognized as the acoustic sound signal 5 by the master unit 1 or any other unit connected thereto. Furthermore, the signal processor may provide the data signal 13 “normalized”, i.e., the data signal 13 is adapted to represent the acoustic sound signal 4 when having a given sound pressure level and/or spectrum. Normalization is useful when the signal of a plurality of the microphones 4 is to be combined. When employing a plurality of microphones 4, the data signal 13 may have a frame structure 34 including a header portion 35 and time-multiplexed channels 36 (time slots) each of which is assigned to a particular microphone 4 (slave unit 2). The header portion 35 as well as the whole frame structure may be determined by the master unit 1. Each of the slave units 2 may be identified by a unique address input into the slave unit 2 by a respective binary word 37.

As described above, the microphone link system includes a master unit and one or more microphones connected to one or more slave units. The slave units may include a digital signal processor (DSP) that may execute program instructions associated with one or more digital algorithms to alter the digital sound signal representing the acoustic sound signal. Alternatively, the electrical sound signals from the microphones may be delivered without any modification. The master unit provides data signals collected from the slave units to other units and controls the microphone link system. Furthermore, it supplies power for slave and listening units. It may also deliver the master clock signal, e.g., 24 or 48 kHz.

Such a system can be used for example in a car, a building, open air etc. The position of the microphones relative to the system may be stationary or mobile e.g., in a car or on stage. If several different microphones are used or the mounting conditions influence the characteristics of the microphone, the audio signal may be modified such that a normalized audio signal is delivered. To allow use in, for example, a hands-free mobile communication a very low signal delay may be provided.

The master unit 1 controls and monitors the system via a separate control channel. This may be used to detect slave units connected to the bus, update the program code of the slave units, send parameters to the slave units or detect disconnects of the link. The optional listener unit can also receive the data signals for further processing. The bus connecting the master to the slave units may be a wired connection and may have a chain, star or even ring topology. Ring topology allows proper function even if a link break occurs in that the master unit is able to detect the break and switch into a mode in which two chains are supported.

The microphone link wire may, as already described above, be realized by a simple unshielded twisted pair. This wire is used for different signals in different frequency ranges (frequency bands). On DC it carries the power supply for the slave units connected to the system. This may also work as a system on/off identifier. In the medium frequency range (e.g., at 10 kHz) control signals can be exchanged between the master and slave units (bidirectional communication). In a higher frequency range (e.g., >>100 kHz) the audio data signal is transmitted. This signal may have a small amplitude and be a differential signal to keep electrical interference low.

The audio data clock (together with the frame) is set by the master unit. For example, if the system supports sixteen slave units with one microphone per unit and 24 kHz audio sample frequency at 16-bits, the data rate would be 6,538 MBps. Each slave unit supports at least one microphone including power supply of the microphone. The signal is A/D converted and can be filtered by a digital processing unit (DSP).

The master unit may deliver a limited current so that each physical layer of the control channel can send data by pulling down the control channel for a short time. For this communication e.g., the LIN protocol can be used. For EMI reasons, a differential coil as it is used in CAN car networks may be applied. The audio frame signal of the physical layer of the differential signal 8 audio data is enabled only as long as the specific data to be sent by this slave unit has to be transmitted, which allows for the connection of all devices in a chain-, star-, or combined topology.

Although the present invention has been illustrated and described with respect to several preferred embodiments thereof, various changes, omissions and additions to the form and detail thereof, may be made, without departing from the spirit and scope of the invention.

What is claimed is:

1. A microphone link system comprising: a microphone that converts an acoustic sound signal into an electrical sound signal, a slave unit, a master unit, and a bus connecting the slave unit to the master unit; the slave unit comprises:
an analog-to-digital converter that is configured to convert the electrical sound signal into a digital sound signal;
a signal processor that receives and processes the digital sound signal, and provides a data signal; and
a bus interface that is connected between the signal processor and the bus, provides to the slave unit electrical power taken from the bus, sends the data signal to the master unit via the bus, and receives from and sends to the master unit control signals via the bus.

2. The system of claim 1, where the slave unit further comprises a variable gain preamplifier that is connected between the microphone and the analog-to-digital converter and in which the gain is controlled by a first one of the control signals received from the master unit.

3. The system of claim 1, in which the data signal provided by the signal processor provides is representative of a normalized acoustic sound signal.

4. The system of claim 1, where the slave unit generates from the electrical sound signal a second one of the control signals transmitted to the master unit.

5. The system of claim 4, where the second one of the control signals is generated when the acoustic sound signal exceeds and/or falls below a trigger sound level.

6. The system of claim 5, where the slave unit transmits the data signal upon transmission of the second one of the control signals.

7. The system of claim 1, in which a filter is implemented in the signal processor, the filter having controllable filter parameters that are controlled by a third one of the control signals received from the master unit.

8. The system of claim 7, in which the bus is a digital two-wire bus.

9. The system of claim 8, in which power, control signals and the processed electrical sound signal are each transmitted in different frequency bands.

10. The system of claim 9, in which the control signals are transmitted in an asymmetric mode and the data signal is transmitted in a symmetric mode.

11. The system of claim 1, in which the slave unit further comprises a clock generator that provides a clock signal representative of the transmission clock of the transmission of the data signal.

12. The system of claim 1, where the data signals are coded.

13. The system of claim 12, in which the data signal has a frame structure including a header portion, the header portion being controlled by the master unit.

14. The system of claim 1, further comprising at least one further slave unit, the slave units are each identified by unique addresses.

15. The system of claim 14, further comprising at least one listener unit that receives the processed electrical sound signal.
